(19) United States
(12) Patent Application Publication
(10) Pub. No.: US 2016/0365406 A1
(43) Pub. Date: Dec. 15, 2016

(54) DISPLAY DEVICE

(71) Applicant: Japan Display Inc., Tokyo (JP)

(72) Inventors: Masaya ADACHI, Tokyo (JP); Toshihiro SATO, Tokyo (JP); Hajime AKIMOTO, Tokyo (JP)

(21) Appl. No.: 15/175,215

(22) Filed: Jun. 7, 2016

(30) Foreign Application Priority Data
Jun. 12, 2015 (JP) 2015-119108

(51) Int. Cl. H01L 27/32; H01L 51/52

(52) U.S. Cl. CPC H01L 27/3279; H01L 27/3211; H01L 51/5284; H01L 2251/5315; H01L 27/1222

(57) ABSTRACT

A display device includes: a plurality of pixels; a plurality of first wirings extending in a first direction; and a plurality of second wirings extending in a second direction, wherein each of the pixels includes a light-emitting region and a light-transmitting region, the light-transmitting region includes a first light-transmitting region adjacent to the light-emitting region in the first direction and a second light-transmitting region adjacent to the light-emitting region in the second direction, the light-transmitting region is divided into a plurality of regions by at least one wiring of the first and second wirings, and the plurality of regions include a first region with a first width and a second region with a second width, a direction of the first and second widths are a same direction and at least one direction of the first and second directions, and the first width is different from the second width.

### CROSS-REFERENCE TO RELATED APPLICATION

The present application claims priority from Japanese application JP2015-119108 filed on Jun. 12, 2015, the content of which is hereby incorporated by reference into this application.

### BACKGROUND OF THE INVENTION

### 1. Field of the Invention

The present invention relates to a display device.

### 2. Description of the Related Art

In the related art, a so-called transparent display device having a structure in which the other side of a display area can be viewed there through while an image is displayed in the display area is known. For example, Japanese Patent No. 5477963 discloses a transparent organic electro-luminescence (EL) display device including organic light-emitting diode elements that emit white light and color filters disposed on the light-extracting side of the organic light-emitting diode elements, in which the color filter is formed only at an intersecting portion between an anode and a cathode, and a gap between the color filters serves as a transparent light-transmitting region. Moreover, JP 2012-238544 A discloses a transparent display device including a transparent region (light-transmitting region) in one region adjacent to a plurality of sub-pixels (see FIG. 14(b) in JP 2012-238544 A).

It is an object of the invention to improve transmission properties in a display device including a light-transmitting region.

### SUMMARY OF THE INVENTION

(1) An aspect of the invention is directed to a display device including: a plurality of pixels arranged in each of a first direction and a second direction intersecting the first direction; a plurality of first wirings extending in the first direction; and a plurality of second wirings extending in the second direction, wherein each of the plurality of pixels includes a light-emitting region and a light-transmitting region, the light-transmitting region includes a first light-transmitting region adjacent to the light-emitting region in the first direction and a second light-transmitting region adjacent to the light-emitting region in the second direction, the light-transmitting region is divided into a plurality of regions by at least one wiring of the plurality of first wirings and the plurality of second wirings, and the plurality of regions include a first region with a first width and a second region with a second width, a direction of the first and second widths are a same direction and at least one direction of the first direction and the second direction, and the first width is different from the second width.

(2) Another aspect of the invention is directed to a display device including: a plurality of pixels arranged in each of a first direction and a second direction intersecting the first direction, wherein each of the plurality of pixels includes a light-emitting region and a light-transmitting region, the light-transmitting region includes a first light-transmitting region adjacent to the light-emitting region in the first direction and a second light-transmitting region adjacent to the light-emitting region in the second direction, the first light-transmitting region and the second light-transmitting region include portions adjacent to each other in the first direction, and the shape of the light-transmitting region is an L-shape composed of the first light-transmitting region and the second light-transmitting region.

### BRIEF DESCRIPTION OF THE DRAWINGS

FIG. 1 is a schematic cross-sectional view schematically showing configurations in the vicinity of a switching element of a display device according to an embodiment.

FIG. 2 is a schematic view schematically showing the overall configuration of the display device according to the embodiment.

FIG. 3 is an equivalent circuit diagram of an active matrix constituting a display area of the display device according to the embodiment.

FIG. 4 is a schematic view schematically showing a wiring structure in one pixel of a display device according to a first embodiment of the invention.

FIG. 5 is a schematic view schematically showing a wiring structure in one pixel of a display device according to a modified example of the first embodiment of the invention.

FIG. 6A is a cross-sectional view showing an edge of a black matrix.

FIG. 6B is a graph showing the relationship between the thickness and position of the black matrix.

FIG. 6C is a graph showing the relationship between the transmittance and position of the black matrix.

FIG. 7 is a schematic view schematically showing a wiring structure in one pixel of a display device according to a second embodiment of the invention.

FIG. 8 is a schematic view schematically showing a wiring structure in one pixel of a display device according to a modified example of the second embodiment of the invention.

FIG. 9A is a schematic view schematically showing a wiring structure in one pixel of a display device according to a third embodiment.

FIG. 9B is a cross-sectional view along A-A of FIG. 9A.

### DETAILED DESCRIPTION OF THE INVENTION

Hereinafter, embodiments of the invention will be described with reference to the drawings.

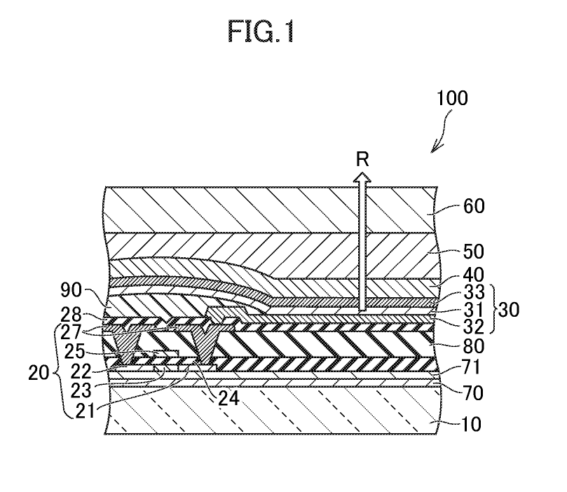

First, the overall configuration of a display device according to first to third embodiments (hereinafter referred to as the “embodiment”) of the invention will be described with reference to FIGS. 1 to 3.

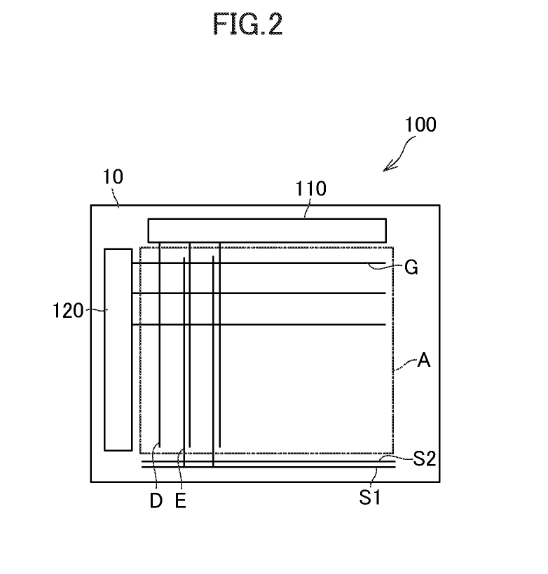

FIG. 1 is a schematic cross-sectional view schematically showing configurations in the vicinity of a switching element of the display device according to the embodiment. A display device 100 according to the embodiment is a so-called transparent display device having a structure in which the other side of a display area A (see FIG. 2) can be viewed therethrough while an image is displayed in the display area A. Moreover, the display device 100 is an actively driven organic light-emitting diode (OLED) display device of a so-called top emission type that extracts light from an organic light-emitting diode 30 in the direction (direction of the arrow R in FIG. 1) opposite to a substrate 10.

The display device 100 includes, as main configurations, the substrate 10, a switching element 20, the organic light-emitting diode 30, a sealing material 40, a filling material 50, and a transparent substrate 60, and has a structure in which they are stacked on top one another. In the embodiment, a configuration of using an organic light-emitting diode as a light-emitting element is employed; however, the light-emitting element is not limited to this configuration, and, for example, a configuration of using a so-called quantum dot may be employed.

The switching element 20 includes a polysilicon thin film transistor. The polysilicon thin film transistor includes source/drain regions 21 and 22 and a polysilicon layer 23 including a channel polysilicon layer and the like. Moreover, a first inter-layer insulating film 24, a gate line layer 25, source/drain electrodes 27, and a second inter-layer insulating film 28 are formed on the polysilicon layer 23.

A first under film 70 made of SiNx or the like is provided between the substrate 10 and the switching element 20 for preventing the entry of ions such as sodium or potassium from the substrate 10 into the polysilicon layer 23 and the gate line layer 25. A second under film 71 made of SiOx or the like is provided between the first under film 70 and the polysilicon layer 23. An insulating film 80 is provided on the second under film 71.

In the embodiment, glass is used as the substrate 10; however, the substrate is not limited to glass, and resin or the like maybe used as long as it has insulating properties .

The organic light-emitting diode 30 includes an organic film 31, a lower electrode 32, and an upper electrode 33. One of the lower electrode 32 and the upper electrode 33 functions as an anode while the other functions as a cathode.

The lower electrode 32 is formed so as to cover an area serving as a light-emitting region, and is connected to one of the source/drain electrodes 27 through a hole that penetrates the second inter-layer insulating film 28. A third inter-layer insulating film (hereinafter referred to as “Bank”) 90 is formed on the peripheral edge portion of the lower electrode 32 and a non-light-emitting region where the polysilicon layer 23, the gate line layer 25, and the like are provided. The organic film 31 is formed so as to cover the lower electrode 32, but is separated from the lower electrode 32 by the bank 90 in the non-light-emitting region. The upper electrode 33 is formed so as to cover the organic film 31.

Here, the configuration of the organic film 31 will be described. However, the configuration of the organic film is a well-known technique and therefore shown in a simplified manner in FIG. 1. The organic film 31 is configured by stacking an electron transport layer, a light-emitting layer, and a hole transport layer in this order from the cathode side toward the anode side. An anode buffer layer or a hole injection layer may be disposed between the anode and the hole transport layer. Moreover, the organic film 31 composed of the plurality of layers may include a layer made of an inorganic material. Moreover, an electron injection layer may be provided between the cathode and the electron transport layer. The light-emitting layer and the electron transport layer may be one layer made of a material capable of providing both functions of the light-emitting layer and the electron transport layer.

When a DC voltage is applied to the lower electrode 32 and the upper electrode 33, holes injected from the anode side and electrons injected from the cathode side go through the hole transport layer and the electron transport layer, respectively, to reach the light-emitting layer, and the electrons and holes are recombined. Due to the recombination of the electrons and holes, the organic light-emitting diode 30 emits light at a predetermined wavelength. For improving use efficiency of light emitted from the light-emitting layer, it is preferred that the lower electrode 32 is composed of a material having a high light reflectance. Alternatively, the lower electrode 32 may employ a stacked structure of a transparent conductive film made of, for example, indium tin oxide (ITO) and a reflection film made of, for example, silver.

The sealing material 40 is formed so as to cover the upper electrode 33. It is preferred that the sealing material 40 has high gas barrier properties for preventing moisture or the like from entering the organic light-emitting diode 30 and is transparent to the visible light. For example, as the sealing material 40, a dense inorganic layer such as silicon nitride, or a stacked film composed of an inorganic layer and an organic layer may be used.

The transparent substrate 60 is formed on the sealing material 40 via the filling material 50, which is made of a polymeric material and is transparent.

FIG. 2 is a schematic view schematically showing the overall configuration of the display device according to the embodiment. The region surrounded by the dashed-double dotted line on the substrate 10 in FIG. 2 shows the display area A where an image is displayed. As shown in FIG. 2, a data driver circuit 110 that outputs an image signal to data lines D and a scanning driver circuit 120 that outputs a scanning signal to gate lines G are disposed around the display area A.

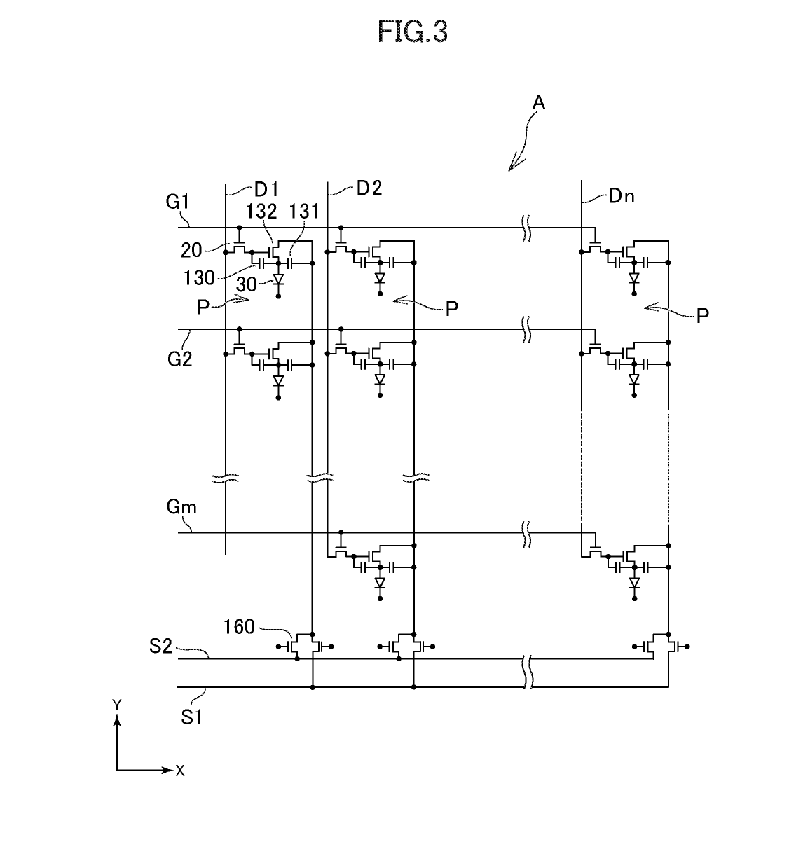

Moreover, in the display area A, potential wirings E are disposed to extend in the same direction as the data line D. The potential wiring E is connected to current supply lines S1 and S2 via a switch 160 (see FIG. 3).

FIG. 3 is an equivalent circuit diagram of an active matrix constituting the display area of the display device according to the embodiment. In the embodiment, the plurality of gate lines G and the plurality of data lines D extending in a direction (second direction Y) intersecting the extending direction (first direction X) of the gate line G are provided on the substrate 10, and as shown in FIG. 3, pixels P are disposed in a matrix at the places where m gate lines G and n data lines D intersect. Each of the pixels P is composed of the switching element 20, the organic light-emitting diode 30, a storage capacitor 130, a pixel capacitor 131, and a driver element 132. One electrode of the organic light-emitting diode 30 is connected to the current supply lines S1 and S2 common to all of the pixels, and is kept at a predetermined potential.

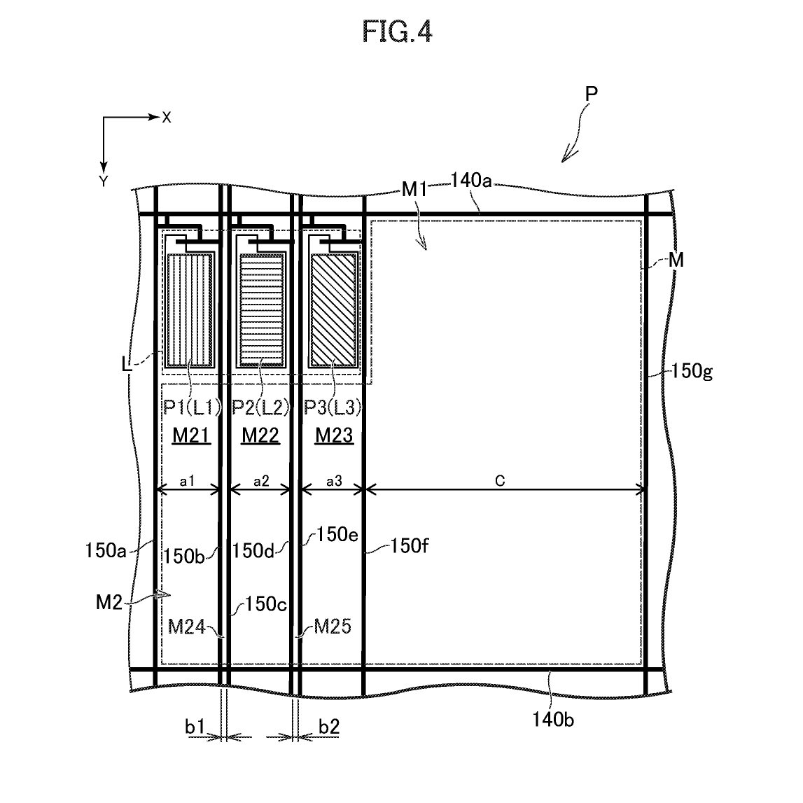

FIG. 4 is a schematic view schematically showing a wiring structure in one pixel of the display device according to the first embodiment of the invention. The display device 100 includes, on the display area A, the plurality of pixels P arranged in each of the first direction X and the second direction Y intersecting (in the first embodiment, orthogonal to) the first direction X for displaying an image, and FIG. 4 shows one of the plurality of pixels P arranged.

Each of the pixels P includes a light-emitting region L (region in the broken line in FIG. 4) that emits light with luminance controlled. Moreover, each of the pixels P includes a light-transmitting region M (region in the broken line in FIG. 4) having a shape adjacent to the light-emitting region L in the first direction X and the second direction Y. Specifically, the light-transmitting region M has a shape composed of a first light-transmitting region M1 that is adjacent to the light-emitting region L in the first direction X and located to extend in the second direction Y beyond the light-emitting region L, and a second light-transmitting region M2 that is adjacent to the light-emitting region L in the second direction Y (in FIG. 4, a shape such as obtained by horizontally flipping the shape of the letter L; so-called L-shape). In other words, the first light-transmitting region M1 is adjacent to both the light-emitting region L and the second light-transmitting region M2 in the first direction X, and the light-transmitting region M has the L-shape composed of the first light-transmitting region M1 and the second light-transmitting region M2.

Moreover, each of the pixels P includes a plurality of sub-pixels in the light-emitting region L. In the first embodiment, the pixel P includes three kinds of sub-pixels: a sub-pixel P1 whose emission color is red; a sub-pixel P2 whose emission color is green; and a sub-pixel P3 whose emission color is blue. The light-emitting region L is composed of a plurality of sub-light-emitting regions L1, L2, and L3 that emit light with luminance controlled in the respective plurality of sub-pixels. The sub-light-emitting region L1 is a region that emits light with the sub-pixel P1 whose emission color is red; the sub-light-emitting region L2 is a region that emits light with the sub-pixel P2 whose emission color is green; and the sub-light-emitting region L3 is a region that emits light with the sub-pixel P3 whose emission color is blue.

Further, the display device 100 includes, in the pixel, a plurality of wirings including the gate line G and the data line D as described with reference to FIGS. 2 and 3, and these wirings are located also in the light-transmitting region M. The wiring has a predetermined width, and the wirings located in the light-transmitting region M block a portion of the light that passes through the light-transmitting region M.

Here, the display device 100 according to the first embodiment has a feature in the arrangement of the wirings blocking the light in the light-transmitting region M, regardless of the kind of the wiring such as whether the wiring disposed in one pixel shown in FIG. 4 is the gate line G or the data line D. Therefore, in the following description, wirings that extend in the first direction X are referred to as “first wirings 140”, while wirings that extend in the second direction Y are referred to as “second wirings 150”.

As shown in FIG. 4, in the first embodiment, a region surrounded by a first wiring 140a, a first wiring 140b, a second wiring 150a, and a second wiring 150g is defined as one pixel. In the vicinity of the position where the first wiring 140a and the second wiring 150a intersect, the three kinds of sub-pixels P1, P2, and P3 are disposed side by side in the first direction X.

The second wiring 150a and a second wiring 150b are arranged so as to interpose the sub-pixel P1 therebetween. A second wiring 150c and a second wiring 150d are arranged so as to interpose the sub-pixel P2 therebetween. A second wiring 150e and a second wiring 150f are arranged so as to interpose the sub-pixel P3 therebetween.

That is, the two second wirings 150b and 150c are arranged so as to pass between the sub-pixel P1 whose emission color is red and the sub-pixel P2 whose emission color is green. Similarly, the two second wirings 150d and 150e are arranged so as to pass between the sub-pixel P2 whose emission color is green and the sub-pixel P3 whose emission color is blue. By employing such an arrangement, the second light-transmitting region M2 of the light-transmitting region M is divided into a plurality of adjacent regions respectively adjacent to the plurality of sub-pixels and intervening regions each interposed between the adjacent regions next to each other. The two second wirings arranged so as to interpose each of the sub-pixels therebetween are the data line and the current supply line.

As shown in FIG. 4, in the light-transmitting region M, the region adjacent to the sub-pixel P1 in the second direction Y is an adjacent region M21; the region adjacent to the sub-pixel P2 in the second direction Y is an adjacent region M22; and the region adjacent to the sub-pixel P3 in the second direction Y is an adjacent region M23. Moreover, the region interposed between the adjacent region M21 and the adjacent region M22 is an intervening region M24; and the region interposed between the adjacent region M22 and the adjacent region M23 is an intervening region M25.

In the first embodiment as has been described above, the light-transmitting region M having the shape adjacent to the light-emitting region L in the first direction X and the second direction Y is included, so that a region occupied by the light-transmitting region M in one pixel can be largely secured and transmission properties are improved.

Moreover, in the first embodiment, the light-transmitting region M is divided into three kinds of regions having different widths in the first direction X: the adjacent regions M21, M22, and M23 whose widths in the first direction X are a1, a2, and a3; the intervening regions M24 and M25 whose widths in the first direction X are b1 and b2; and the first light-transmitting region M1 whose width in the first direction X is c (c>a1, a2, a3>b1, b2).

Here, diffraction of light may occur in the light-transmitting region M due to the influence of the edges of the wirings. The more the portion serving as the edge is increased, the more likely the diffraction occurs. Moreover, when the intervals of the regions divided by the wirings are equal, that is, when there is a periodic structure, the intensity of diffraction of light increases. In the first embodiment, since the light-transmitting region M is divided by the second wirings 150 (150a to 150g) into the regions having different widths and a plurality of different periods exist together, it is possible to suppress an increase in the intensity of diffraction caused by the periodic structure.

In the first embodiment, a configuration is employed in which the width a1, the width a2, and the width a3 of the adjacent regions M21, M22, and M23 in the first direction X are substantially the same; however, the width a1, the width a2, and the width a3 may be configured to be different from one another for further suppressing an increase in the intensity of diffraction. Similarly, for further suppressing an increase in the intensity of diffraction, the width b1 and the width b2 of the intervening regions M24 and M25 in the first direction X may be configured to be different from each other.

In the first embodiment, the light-transmitting region

M is divided into six regions: the adjacent regions M21, M22, and M23; the intervening regions M24 and M25; and the first light-transmitting region M1. However, the light-transmitting region is not limited to this, and it is sufficient that the light-transmitting region M is divided by at least one wiring into a plurality of regions so as to have different widths in at least one of the first direction X and the second direction Y.

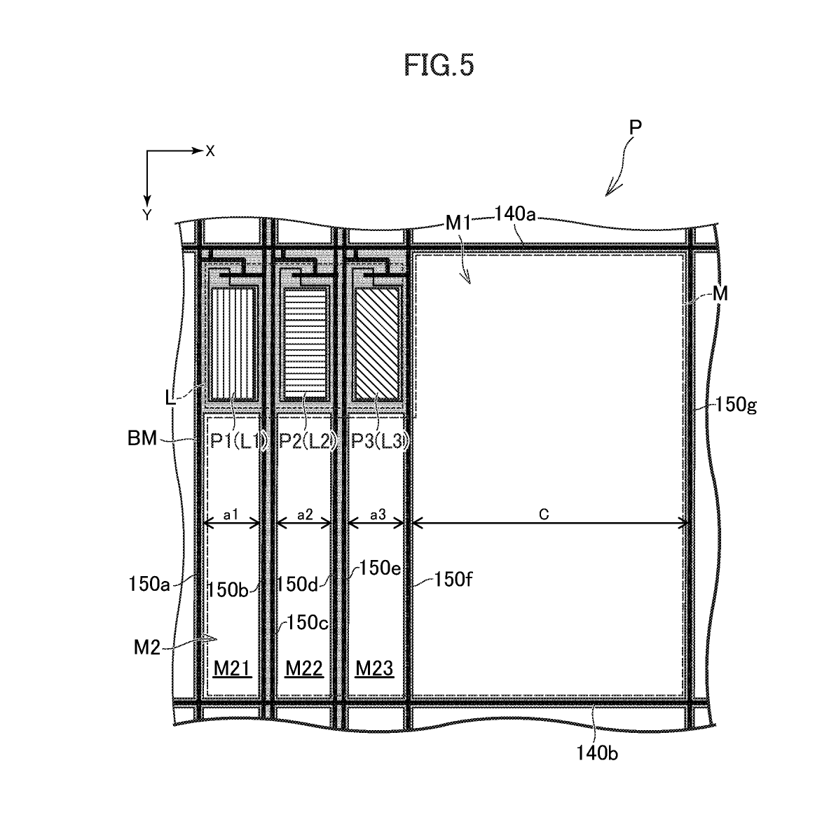

FIG. 5 is a schematic view showing a wiring structure in one pixel of a display device according to a modified example of the first embodiment. The display device according to the modified example of the first embodiment is similar in basic structure, such as the arrangement of wirings, to the configuration of the first embodiment shown in FIG. 4, except that a black matrix BM is provided to cover the wirings. Therefore, a detailed description of the basic structure is omitted.

In the display device according to the modified example of the first embodiment, the black matrix BM is provided to cover the first wirings 140 and the second wirings 150. The intervening regions described with reference to FIG. 4 are filled with the black matrix BM. The portion serving as the edge of the wiring or black matrix is reduced (the number of divided regions is reduced) by an amount corresponding to the intervening regions filled with the black matrix BM in this manner, and therefore, the diffraction is less likely to occur.

Moreover, by employing a structure in which a component including the various wirings, which is made of metal and having reflectivity, is covered by the black matrix BM, the reflection of external light (for example, sunlight) on the component can be greatly suppressed. Accordingly, it is possible to realize a transparent display device capable of greatly suppressing the reflection of external light without reducing the transmittance of the light-transmitting region M, that is, having a high transmittance and easily viewed even under a bright environment.

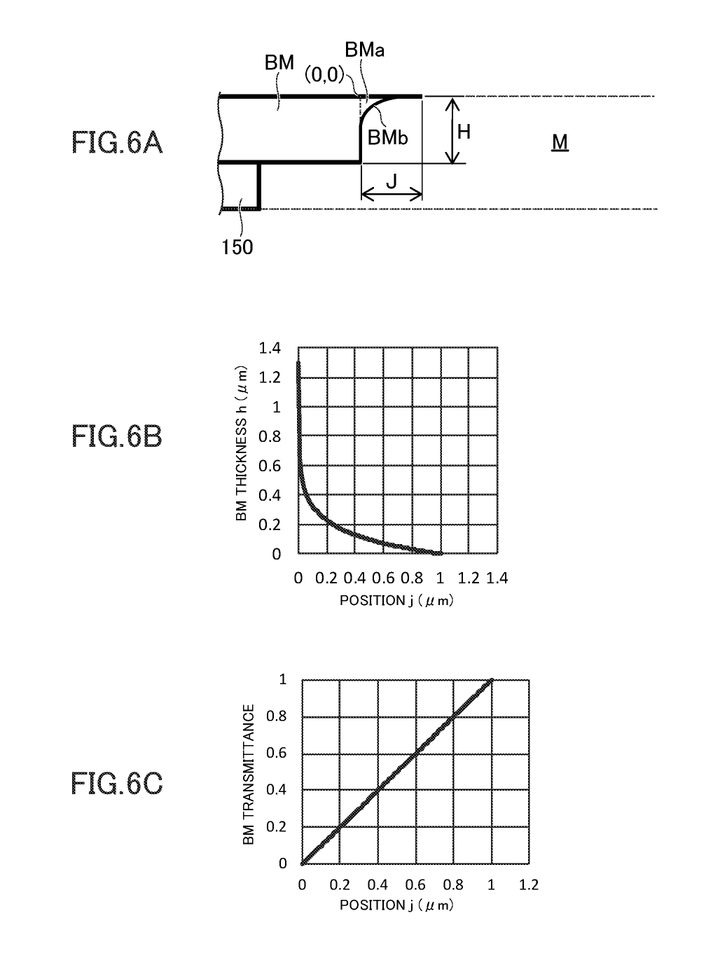

Here, the occurrence of diffraction, which is a problem in a transparent display device, and the suppression of diffraction will be described with reference to FIGS. 6A to 6C. The diffraction is likely to occur when a transmittance in the vicinity of the portion serving as the edge of the wiring or black matrix rapidly changes. By making this change in transmittance constant, it is possible to suppress an increase in the intensity of diffraction. In the modified example of the first embodiment, an edge structure of the black matrix BM is formed into a shape shown in FIG. 6A for making the change in transmittance constant to suppress the occurrence of diffraction.

FIGS. 6A to 6C are diagrams for explaining the edge structure of the black matrix. FIG. 6A is a cross-sectional view showing the edge of the black matrix; FIG. 6B is a graph showing the relationship between the thickness and position of the black matrix; and FIG. 6C is a graph showing the relationship between the transmittance and position of the black matrix.

The black matrix BM includes an edge portion (edge) BMa including an edge face BMb facing an opening (the light-transmitting region M) that penetrates the front surface and the rear surface thereof. The edge face BMb is an inner surface of the opening and intersects the front surface and the rear surface. As shown in FIG. 6A, the edge face BMb is a curved surface inclined such that one of the front surface and the rear surface overhangs from the other, and having a gradient not exceeding 9020 to the other of the front surface and the rear surface. In FIG. 6A, the black matrix BM is directly formed on the wiring (the second wiring 150 in FIG. 6A) disposed on the substrate 10. However, the black matrix BM may be formed in a position superimposed on a wiring of the transparent substrate 60 opposed to the substrate 10.

Further, an ideal configuration as the edge structure of the black matrix BM to suppress an increase in the intensity of diffraction will be described. When the thickness of the edge portion BMa is H and the length of the edge portion BMa in the projecting direction is J, it is desirable to satisfy the relation: J≧1.0 μm. This is because in order to achieve a desired optical function with respect to the visible light, it is desirable to make the size larger than the wavelength of visible light.

Further, when the position in the projecting direction with the position (0, 0) in FIG. 6A as the origin is j and the position of BM in the thickness direction is h, it is desirable to satisfy the relation: h=−Cln(j)+D (C and D are each a constant). FIG. 6B is a graph showing the relationship between the position h and the position j of BM when C=0.141 and D=0. Moreover, FIG. 6C is a graph showing the relationship between the transmittance and the position j when C=0.141 and D=0.

The relationship between the position h of the edge portion BMa in the thickness direction and the position j of the edge portion BMa in the projecting direction is made logarithmic as shown in FIG. 6B, whereby a black matrix whose transmittance linearly changes according to the position in the projecting direction as shown in FIG. 6C is obtained. By forming the edge of the black matrix into such a structure, an increase in the intensity of diffraction is suppressed, color separation of transmitted light is suppressed, and thus a display device with high transparency can be realized.

A similar advantageous effect can be obtained also when the shape of the edge portion (edge) of the black matrix BM of the modified example of the first embodiment is applied to the shape of the edges of the first wiring 140 and the second wiring 150 of the first embodiment.

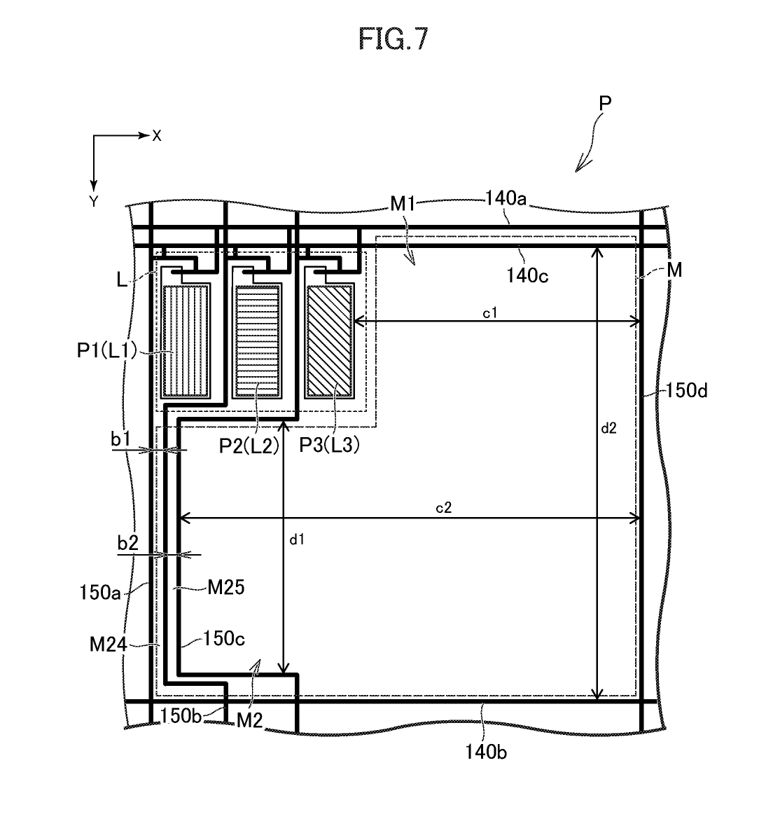

FIG. 7 is a schematic view schematically showing a wiring structure in one pixel of the display device according to the second embodiment. The display device according to the second embodiment is similar in basic structure to the display device according to the first embodiment, except that a wiring structure in one pixel is different.

As shown in FIG. 7, in the second embodiment, the region surrounded by the first wiring 140a, the first wiring 140b, the second wiring 150a, and the second wiring 150d is defined as one pixel. The three kinds of sub-pixels P1, P2, and P3 are disposed side by side in the first direction X in the vicinity of the position where the first wiring 140a and the second wiring 150a intersect.

The second wiring 150a and the second wiring 150b are arranged so as to interpose the sub-pixel P1 therebetween. The second wiring 150b and the second wiring 150c are arranged so as to interpose the sub-pixel P2 therebetween.

The second wiring 150b (third wiring) and the second wiring 150c (fourth wiring) extend from the sub-light-emitting regions L2 and L3, while bending so as to be away from the first light-transmitting region M1 and approach the second wiring 150a, to the edge portion of the pixel.

With the wiring structure described above, the light-transmitting region M is divided into three region: the intervening region M24 interposed between the second wiring 150a and the second wiring 150b; the intervening region M25 interposed between the second wiring 150b and the second wiring 150c; and a region other than those.

In the second embodiment as shown in FIG. 7, in the light-transmitting region M, a width c2 across the first light-transmitting region M1 and the second light-transmitting region M2 in the first direction X is larger than a width c1 across the first light-transmitting region M1 in the first direction X. Moreover, in the light-transmitting region M, a width d2 across the first light-transmitting region M1 in the second direction Y is larger than a width d1 across the second light-transmitting region M2 in the second direction Y.

In the second embodiment as has been described above, the light-transmitting region M having the shape adjacent to the light-emitting region L in the first direction X and the second direction Y is included, so that a region occupied by the light-transmitting region M in one pixel can be largely secured and transmission properties are improved.

Moreover, in the second embodiment, the light-transmitting region M is divided into regions including regions having different widths in the first direction X: the intervening regions M24 and M25 including the regions whose widths in the first direction X are b1 and b2; the first light-transmitting region M1 including the region whose width in the first direction X is c1; and the region including the first light-transmitting region M1 and the second light-transmitting region M2 which include the region whose width in the first direction X is c2 (c2>c1>b1, b2). It can also be said that the light-transmitting region M is divided into regions including regions having different widths in the second direction Y: the second light-transmitting region M2 including the region whose width in the second direction Y is d1; and the first light-transmitting region M1 including the region whose width in the second direction Y is d2. Since the light-transmitting region M is divided into the plurality of regions including the regions having different widths, an increase in the intensity of diffraction is suppressed. Moreover, the light-transmitting region M is divided into three regions in the second embodiment, and the number of regions obtained by dividing the light-transmitting region M is reduced compared with the first embodiment in which the light-transmitting region M is divided into six regions. Therefore, the intensity of diffraction is less likely to increase by an amount corresponding to the reduced number of regions.

Moreover, in the second embodiment, the lengths of the second wirings 150a, 150b, and 150c are different from one another. When the same material is used for wirings having different lengths, the wiring resistance varies depending on the wiring, and thus a problem is caused in display characteristics. Therefore, it is preferred that materials whose resistivities per unit length are different from each other are used for the wirings having different lengths. Specifically, it is preferred that the resistivity per unit length of the second wiring 150a, which is shortest, is made higher than the resistivities per unit length of the other wirings, the resistivity per unit length of the second wiring 150b (third wiring), which is second shortest, is made lower than that of the second wiring 150a, and the resistivity per unit length of the second wiring 150c (fourth wiring), which is longest, is made lower than those of the other wirings.

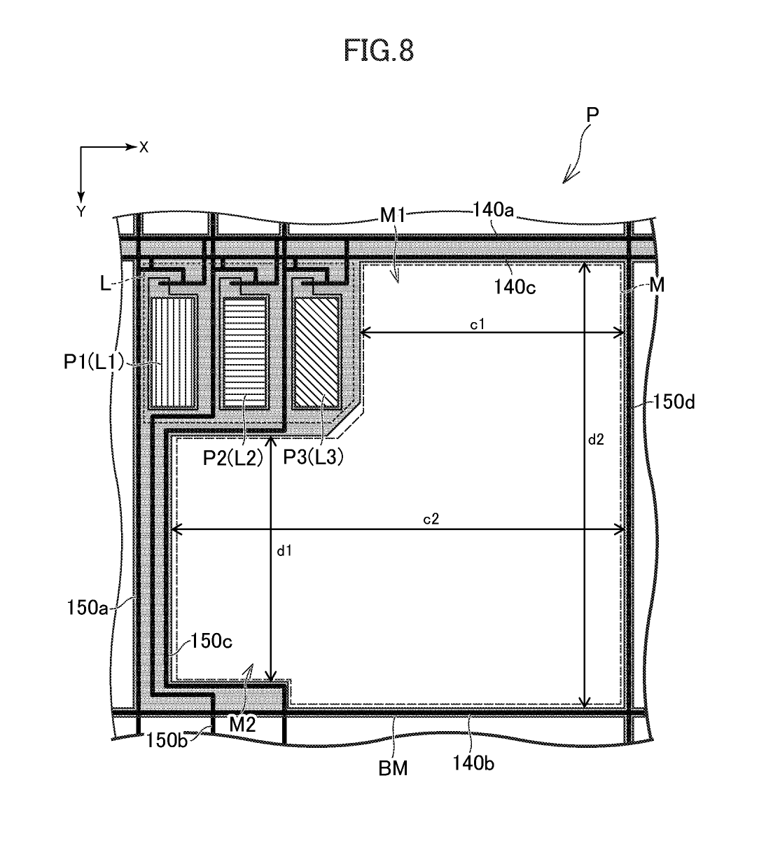

FIG. 8 is a schematic view showing a wiring structure in one pixel of a display device according to a modified example of the second embodiment. The display device according to the modified example of the second embodiment is similar in basic structure, such as the arrangement of wirings, to the configuration of the second embodiment shown in FIG. 7, except that the black matrix BM is provided to cover the wirings. Therefore, a detailed description of the basic structure is omitted.

In the display device according to the modified example of the second embodiment, the black matrix BM is provided to cover the first wirings 140 and the second wirings 150. The intervening regions described with reference to FIG. 7 are filled with the black matrix BM, and accordingly, the number of divisions of the light-transmitting region M is reduced by an amount corresponding to the filled intervening regions. Thus, the display device has a configuration in which the intensity of diffraction is less likely to increase. Although a description is omitted herein, it is preferred also in the modified example of the second embodiment that the edge structure of the black matrix BM has s the configuration described with reference to FIGS. 6A to 6C.

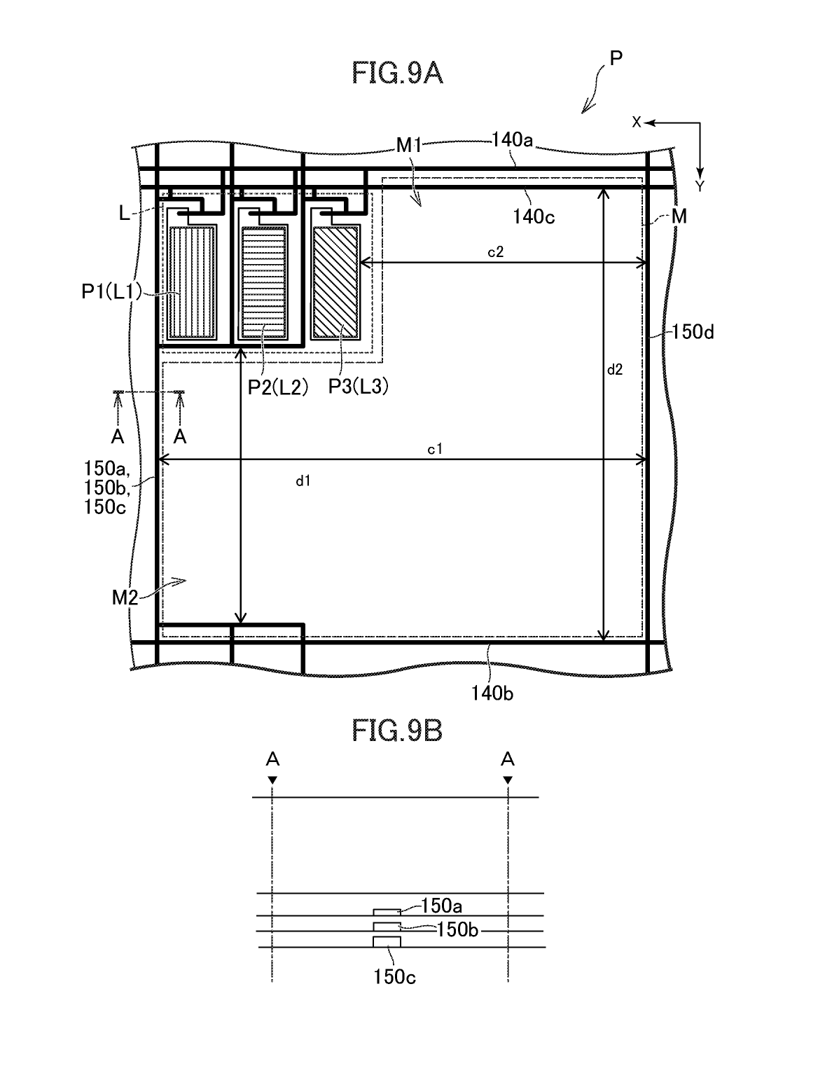

FIGS. 9A and 9B are diagrams for explaining the display device according to the third embodiment. FIG. 9A is a schematic view schematically showing a wiring structure in one pixel of the display device according to the third embodiment; and FIG. 9B is a cross-sectional view along A-A of FIG. 9A. The display device according to the third embodiment is similar in basic structure to the display device according to the second embodiment, except that the wiring structure in one pixel is different.

In the third embodiment, different from the second embodiment employing the configuration in which the plurality of second wirings 150 are disposed at predetermined intervals, the plurality of second wirings 150 overlap in the thickness direction (are superimposed on one another as viewed planarly) at the edge portion of the pixel, and are provided along the edge portion of the pixel. Specifically, the second wiring 150b and the second wiring 150c extend from the sub-light-emitting regions L1 and L2 while bending so as to overlap the second wiring 150a in the thickness direction. In the third embodiment as described above, the second light-transmitting region M2 has a configuration of being not divided by the wirings, and the light-transmitting region M is composed of one region. Therefore, compared with the first embodiment and the second embodiment, the edge portion of the wiring is reduced, and the intensity of diffraction is less likely to increase.

Moreover, as shown in FIG. 9B, the thickness of the plurality of second wirings is reduced as the length thereof is shorter. That is, the thickness of the second wiring 150a, which is shortest, is made thinnest, whereby the resistivity per unit length of the second wiring 150a is made larger than those of the other wirings. Then, the thicknesses of the second wiring 150b and the second wiring 150c are increased in this order to reduce the resistivity per unit length. Also in the plurality of second wirings in the second embodiment described above, the structure described in the third embodiment in which the thickness of the wiring is reduced as the length thereof is shorter may be applied.

Although not shown in the drawing, the configuration of providing the black matrix BM so as to cover the wirings may be employed also in the third embodiment, similarly to that shown in the modified example of the first embodiment and that shown in the modified example of the second embodiment.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a plurality of pixels arranged in each of a first direction and a second direction intersecting the first direction;
a plurality of first wirings extending in the first direction; and
a plurality of second wirings extending in the second direction, wherein
each of the plurality of pixels includes a light-emitting region and a light-transmitting region,
the light-transmitting region includes a first light-transmitting region adjacent to the light-emitting region in the first direction and a second light-transmitting region adjacent to the light-emitting region in the second direction,
the light-transmitting region is divided into a plurality of regions by at least one wiring of the plurality of first wirings and the plurality of second wirings, and
the plurality of regions include a first region with a first width and a second region with a second width,
a direction of the first and second widths are a same direction and at least one direction of the first direction and the second direction, and
the first width is different from the second width.

2. The display device according to claim 1, wherein
the first light-transmitting region and the second light-transmitting region include portions adjacent to each other in the first direction, and
a shape of the light-transmitting region is an L-shape composed of the first light-transmitting region and the second light-transmitting region.

3. The display device according to claim 1, wherein
each of the plurality of pixels includes a plurality of sub-pixels,
the plurality of sub-pixels include sub-light-emitting regions respectively,
the light-emitting region is composed of the sub-light-emitting regions,
two of the second wirings are arranged so as to pass between two of the sub-pixels next to each other, and extend to the second light-transmitting region,
the second light-transmitting region is divided by the two of the second wirings into two adjacent regions and an intervening region interposed between the two adjacent regions,
each of the two adjacent regions is adjacent to each of the two of the sub-pixels in the second direction, and
the intervening region is a region between the two of the second wirings.

4. The display device according to claim 3, wherein
the two of the second wirings are a data line and a current supply line.

5. The display device according to claim 1, further comprising a black matrix covering the plurality of first wirings and the plurality of second wirings.

6. The display device according to claim 5, wherein
the black matrix includes a front surface, a rear surface facing the front surface, an opening, and an edge face facing the opening,
the opening penetrates the black matrix from the front surface to the rear surface,
the edge face is an inner surface of the opening and intersects the front surface and the rear surface, and
the edge face is a curved surface inclined such that one of the front surface and the rear surface overhangs from an other of the front surface and the rear surface.

7. A display device comprising:
a plurality of pixels arranged in each of a first direction and a second direction intersecting the first direction, wherein
each of the plurality of pixels includes a light-emitting region and a light-transmitting region,
the light-transmitting region includes a first light-transmitting region adjacent to the light-emitting region in the first direction and a second light-transmitting region adjacent to the light-emitting region in the second direction,
the first light-transmitting region and the second light-transmitting region include portions adjacent to each other in the first direction, and
a shape of the light-transmitting region is an L-shape composed of the first light-transmitting region and the second light-transmitting region.

8. The display device according to claim 7, wherein
each of the plurality of pixels includes a plurality of sub-pixels arranged in the first direction,
the plurality of sub-pixels include sub-light-emitting regions respectively,
the light-emitting region is composed of the sub-light-emitting regions,
a second wiring extending in the second direction is disposed between the plurality of the sub-pixels, and
the second wiring is bent between the sub-light-emitting regions and the second light-transmitting region so as to be away from the first light-transmitting region, and extends in the first direction to an edge portion of one of the pixels.

9. The display device according to claim 8, wherein
a second wiring includes a plurality of second wirings, and
the plurality of second wirings are bent at the edge portion so as to be away from the light-emitting region, and extend along the edge portion in the second direction while being adjacent to each other.

10. The display device according to claim 8, wherein
a second wiring includes a plurality of second wirings, and
the plurality of second wirings are bent at the edge portion so as to be away from the light-emitting region, and extend along the edge portion in the second direction while being superimposed on each other as viewed planarly.

11. The display device according to claim 9, wherein
the plurality of second wirings include a third wiring and a fourth wiring located between the first light-transmitting region and the third wiring in the light-emitting region, and
the fourth wiring has a resistance value per unit length smaller than that of the third wiring.

12. The display device according to claim 9, wherein
the plurality of second wirings include a third wiring and a fourth wiring located between the first light-transmitting region and the third wiring in the light-emitting region, and
a thickness of the fourth wiring is larger than a thickness of the third wiring.

13. The display device according to claim 8, further comprising a black matrix covering the second wiring.

14. The display device according to claim 13, wherein
the black matrix includes a front surface, a rear surface facing the front surface, an opening, and an edge face facing the opening,
the opening penetrates the black matrix from the front surface to the rear surface,
the edge face is an inner surface of the opening and intersects the front surface and the rear surface, and
the edge face is a curved surface inclined such that one of the front surface and the rear surface overhangs from an other of the front surface and the rear surface.
